(19) United States
(12) Patent Application Publication
(10) Pub. No.: US 2025/0349569 A1
(43) Pub. Date: Nov. 13, 2025

(54) METHOD AND SYSTEM FOR DEPOSITING A NANO-OBJECT ON A RECEIVING SURFACE AND FASTENING SYSTEM INCORPORATING SUCH A DEPOSITION SYSTEM

(71) Applicant: C12 QUANTUM ELECTRONICS, PARIS (FR)

(72) Inventors: Joey Sulpizio, Paris (FR); Romaric Le Goff, Montrouge (FR)

(21) Appl. No.: 18/868,564

(22) PCT Filed: May 23, 2023
(86) PCT No.: PCT/EP2023/063826

§ 371 Date: Nov. 22, 2024

(30) Foreign Application Priority Data
May 23, 2022 (FR) FR2204924

(51) Int. Cl. H01L 21/67; B82Y 10/00

(52) U.S. Cl. CPC H01L 21/67121; B82Y 10/00

(57) ABSTRACT

A method for depositing a nano-object on a receiving surface comprises a first step of picking up this nano-object located on a carrying surface, a step of transferring the picked-up nano-object to the receiving surface, and a step of depositing the nano-object on the receiving surface. A cantilever transfer device comprising two spaced-apart arms is used to pick up, hold and release the nano-object.

### CROSS-REFERENCE TO RELATED APPLICATIONS

This application is a national phase entry under 35 U.S.C. § 371 of International Patent Application PCT/EP2023/063826, filed May 23, 2023, designating the United States of America and published as International Patent Publication WO 2023/227621 A1 on Nov. 30, 2023, which claims the benefit under Article 8 of the Patent Cooperation Treaty of French Patent Application Serial No. FR2204924, filed May 23, 2022.

### TECHNICAL FIELD

The present disclosure relates to a method and a system for depositing a nano-object on a receiving surface. It is also aimed at a fastening system incorporating such a deposition system. The field of the present disclosure is more particularly that of quantum components and systems.

### BACKGROUND

Depositing nanotubes on a surface is currently a real technological challenge, due to the very small dimensions of these nanotubes. It is even more difficult when it comes to depositing a nanotube on two electrodes separated by a trench.

The paper “One-step Direct Transfer of Pristine Signe-Walled Carbon Nanotubes for Functional Nanoelectronics,” Chung Chiang Wu et al, Nanoletters 2010, [1], discloses a one-step direct transfer technique for fabricating functional nanoelectronic devices using pristine single-walled carbon nanotubes (SWNTs). Suspended SWNTs grown by the chemical vapor deposition (CVD) method are aligned and directly transferred onto pre-configured device electrodes at room temperature.

The paper “Fork stamping of pristine carbon nanotubes onto ferromagnetic contacts for spin-valve devices,” J. Gramich et al., Phys. Status, 2015 [2], discloses a manufacturing method called “fork stamping” optimized for the dry transfer of individual virgin carbon nanotubes (CNTs) onto ferromagnetic contact electrodes manufactured by standard lithography.

The paper “Transfer of carbon nanotubes onto microactuators for hysteresis-free transistors at low thermal budget” M. Muoth and C. Hierold, 2012 IEEE 25th International Conference on Micro Electro Mechanical Systems (MEMS), 2012, pp. 1352-1355, doi: 10.1109/MEMSYS.2012.6170417, [3], discloses a dry transfer method for single-walled carbon nanotubes, enabling ultrapure, hysteresis-free suspended nanotube field-effect transistors on microactuated electrodes without exposing the device chip to high nanotube growth temperatures. The nanotubes are grown on a separate matrix, between the arms of a forked structure, and then transferred to receiving electrodes on a device matrix. The device's matrix is kept at room temperature, so it can in principle contain temperature-sensitive readout circuits. Liquid-free transfer at room temperature is performed under optical microscope observation, while placement is detected by monitoring the current through the device's electrodes.

The document WO2020/079228A1 (Delbecq et al.) discloses a method and device for depositing a nano-object, comprising-approaching, in an enclosure, a support in the direction of a carrier substrate, then-transferring, in the enclosure, the object from the support to a deposition zone on the carrier substrate. The transfer step is preferably carried out while the inside of the enclosure is under vacuum at a pressure of less than 10-6 bar.

As an example of prior art, a fastening chamber 2 maintained under advanced ultra-high vacuum (UHV) is an integral part of nanofabrication equipment 1 as shown in FIG. 1. The fastening chamber comprises a chip 20 equipped with electrodes 23, onto which a carbon nanotube initially present on cantilever electrodes 23 extending a circuit or electronic chip 21 is to be deposited, with reference to FIGS. 2 to 5.

Current methods for assembling Qubit components use a nanotube fastening technique wherein it is difficult to control the angle of approach of the chip 21 provided with nanotube-bearing electrodes 23 to the plane of the receiving chip, as shown in FIG. 6. It is also virtually impossible to position the nanotubes precisely and to determine when a nanotube has stopped transferring along the vertical axis.

Furthermore, the receiving surface is generally provided with large trenches, which could be a source of degradation of the resonator's quality factor. Furthermore, the fastening technique is not scalable beyond a few Qubits. What's more, navigation inside a fastening tool is particularly difficult.

A first solution was to get rid of the trench entirely by working with a chip with electrodes on an arm instead of electrodes over a trench. A problem with this design is that it would change the whole nanofabrication process. The aim is to solve the problem without changing the chip design.

Hierold et al, 2012 came up with the idea of building the chip on a cantilever, so that the transfer of the carbon nanotube is simply a transfer between two cantilevers. This was not possible, as it would require a substantial change in chip design.

### BRIEF SUMMARY

One aim of the present disclosure is to propose a new technique for transferring a nano-object onto an electronic chip/circuit in a coherent manner, with as few defects as possible on the resulting chip, as quickly as possible and as scalably as possible.

According to a first aspect, the objective of the present disclosure is thus achieved with a method for depositing a nano-object, this nano-object initially being located on a cantilever chip having a comb structure, characterized in that it comprises: a step of picking up this nano-object, this picking-up step implementing a cantilever device or transfer fork comprising two arms spaced apart each provided with a tine, the two tines facing one another and arranged to pick up, hold, and release the nano-object, a step for transferring the picked-up nano-object to the receiving surface, and a step for depositing the nano-object onto the receiving surface.

According to a second aspect, the objective of the present disclosure is thus achieved with a method for depositing a nano-object on a receiving surface comprising a first step of picking up this nano-object located on a carrying surface, a step of transferring the picked-up nano-object to the receiving surface, and a step of depositing the nano-object on the receiving surface, which method is characterized in that it use a cantilever transfer device comprising two spaced-apart arms arranged to pick up, hold and release the nano-object.

Other advantageous and non-limiting features of the present disclosure, taken alone or in any technically feasible combination, can be combined with the first aspect or the second aspect.

In particular, a deposition method is provided for depositing a nano-object, or at least one nano-object, in particular, at least one carbon nanotube, onto a receiving surface, comprising a first step for picking up this nano-object, or at least one nano-object, or at least one carbon nanotube, arranged on a carrying surface, in particular, a cantilever chip or a cantilever semiconductor chip.

According to one embodiment, the at least one nano-object is initially arranged on cantilever electrodes, in particular, cantilever electrodes of a cantilever chip or a cantilever semiconductor chip.

Preferably, the cantilever transfer device or transfer fork comprises two spaced-apart arms each provided with a tine, the two tines facing each other and arranged to pick up, hold and release the nano-object, or carbon nanotube.

When the method according to the present disclosure is implemented for the deposition of at least one nano-object or at least one carbon nanotube, the carrying surface may comprise a cantilever semiconductor chip.

When the method according to the present disclosure is implemented for the fastening of at least one nano-object or at least one carbon nanotube, the carrying surface may comprise a cantilever semiconductor chip.

The deposition method according to the present disclosure can be advantageously implemented for the deposition of at least one nanotube, preferably at least one carbon nanotube, on electrodes separating trenches.

Preferably, during the step of depositing at least one nano-object, or nanotube or several nanotubes, the arms of the cantilever transfer device penetrate two trenches surrounding an electrode.

These electrodes can be advantageously arranged to produce Qubit components.

Using the deposition method described herein, it is possible to deposit nano-objects or nanotubes on circuits with inter-electrode trenches less than 100 μm wide, typically 30 μm.

Preferably, a step is provided for detecting when the cantilever transfer device has come into contact with the receiving surface, this detection step implementing an atomic force probe comprising a tip carrying the cantilever transfer device and attached to a tuning fork or mechanical resonator frequency-controlled around a predetermined resonant frequency.

Preferably, the detection step comprises a step for providing distance information between the tip carrying the cantilever transfer device and the receiving surface, the distance information being processed to control the transfer step.

According to one example, the method is implemented for depositing at least one nanotube, in particular, at least one carbon nanotube, on a microelectronic circuit.

Preferably, the transfer step of the at least one nanotube, in particular, at least one carbon nanotube, is arranged to deposit the nanotube on electrodes.

According to any embodiment, the method can be implemented in the production of a Qubit component.

According to another aspect of the present disclosure, a system is proposed for depositing at least one nano-object on a receiving surface, implementing the deposition method according to the present disclosure, comprising means for picking up this nano-object located on a carrying surface, preferably a cantilever chip, means for transferring the picked-up nano-object to the receiving surface, and means for depositing the nano-object on the receiving surface. It comprises, as the picking-up, transferring and depositing means, at least one cantilever transfer device or at least one transfer fork comprising two spaced-apart arms arranged to pick up, hold and release the nano-object.

In particular, a deposition system is proposed for depositing a nano-object on a receiving surface, implementing the deposition method according to the present disclosure, comprising means for picking up this nano-object located on a carrying surface.

Preferably, the at least one cantilever transfer device or the at least one transfer fork comprises two spaced-apart arms each provided with a tine, these tines facing each other and arranged to pick up, hold and release the nano-object.

Preferably, the cantilever transfer device can be in the form of two substantially parallel blades separated by an insulating piece.

Each blade may, for example, comprise an elongated portion with a cantilevered end having an arm substantially perpendicular to the elongated portion.

These arms may comprise an electrically conductive coating.

The system according to the present disclosure can be advantageously implemented for the deposition of at least one carbon nanotube on electrodes separated by trenches.

Preferably, the trenches between the electrodes are less than 100 μm wide.

Preferably, the system is implemented in a system for fastening nanotubes, in particular, carbon nanotubes, onto a plurality of electrodes of an electronic circuit of a quantum dot.

In a particular implementation of the present disclosure, a system for fastening nanotubes, in particular, carbon nanotubes, onto a plurality of electrodes is proposed, comprising a deposition system according to the present disclosure, a fastening device and a device for receiving an electronic circuit of a quantum dot.

Preferably, the system further comprises means for detecting when the cantilever transfer device has come into contact or is at risk of contact with the receiving surface, the detection means comprising an atomic force probe having a tip carrying the cantilever transfer device and attached to a tuning fork frequency-controlled around a predetermined resonant frequency.

Preferably, the detection means further comprises means for outputting deviation information between the tip carrying the cantilever transfer device and the receiving surface, and further comprises means for controlling the transfer means on the basis of the deviation information.

According to one embodiment, the system is arranged in a fastening chamber within a system for producing Qubit components.

According to one embodiment, a system for fastening carbon nanotubes to produce Qubit components is provided, comprising a fastening chamber incorporating a deposition system according to one of the preceding features.

The present disclosure involves transferring the carbon nanotube onto a single small cantilever intermediate. This allows the trench to be much smaller, saving space on the chip for future upgradeable design.

### REFERENCES

[1] “One-step Direct Transfer of Pristine Signe-Walled Carbon Nanotubes for Functional Nanoelectronics,” Chung Chiang Wu et al, Nanoletters 2010
[2] “Fork stamping of pristine carbon nanotubes onto ferromagnetic contacts for spin-valve devices,” J. Gramich et al., Phys. Status, 2015
[3] “Transfer of carbon nanotubes onto microactuators for hysteresis-free transistors at low thermal budget” M. Muoth and C. Hierold, 2012 IEEE 25th International Conference on Micro Electro Mechanical Systems (MEMS), 2012, pp. 1352-1355, doi: 10.1109/MEMSYS.2012.6170417
[4] MicroMegascope (Canale et al.), arXiv: 1805.05231v1 [physics.ins-det] 14 May 2018

### BRIEF DESCRIPTION OF THE DRAWINGS

FIG. 1 is a perspective view of a prior art fastening chamber;

FIG. 2 is a view of the inside of the fastening chamber in FIG. 1;

FIG. 3 shows a receiving substrate and a multi-electrode circuit implemented in a prior art deposition method;

FIG. 4 shows an example of a cantilever array chip approaching two trenches separated by a set of aligned electrodes, as in the prior art;

FIG. 5 shows an example multi-electrode circuit implemented in a prior art deposition method;

FIG. 6 shows an example, in the prior art, of an approach made difficult by imperfect angle control of the multi-electrode circuit of FIG. 5 on a receiving substrate in the prior art.

FIG. 7 shows an example of a cantilever transfer device used in a nanotube deposition system according to the present disclosure;

FIG. 8 is an enlarged view of one end of the cantilever transfer device of FIG. 7;

FIG. 9 shows a nanotube on a multi-electrode circuit;

FIG. 10 shows a top view and a side view of an approach to a cantilever transfer device, for a first transfer of the nanotube of FIG. 9;

FIG. 11 shows a nanotube transfer situation using a cantilever transfer device;

FIG. 12 shows an approach to a cantilever transfer device for a second nanotube transfer;

FIG. 13 shows the cantilever transfer device of FIG. 12, carrying the nanotube that has come into contact with the electrodes, for a second transfer;

FIG. 14 shows the nanotube on the substrate after the second transfer;

FIG. 15 shows the drastic reduction in the size of a trench made possible by the deposition method according to the present disclosure;

FIG. 16 shows the space saved by reducing the size of the trenches;

FIG. 17 shows an exemplary embodiment of the deposition method according to the present disclosure;

FIG. 18 is a perspective view of an exemplary embodiment of a fastening system according to the present disclosure;

FIG. 19 is a cutaway view of the fastening system shown in FIG. 18;

FIG. 20 is an enlarged view of the interior of the fastening system shown in FIGS. 18 and 19;

FIG. 21 shows a top view of an AFM device fitted to the fastening system shown in FIGS. 18, 19 and 20, and an enlarged view of an electronic circuit treated with the deposition method according to the present disclosure;

FIG. 22 is an enlarged perspective view of the AFM device shown in FIG. 21;

FIG. 23 is an enlarged view of the cantilever transfer device coupled to the AFM device of FIG. 22; and

FIG. 24 is a detailed view of the AFM device shown in FIG. 23.

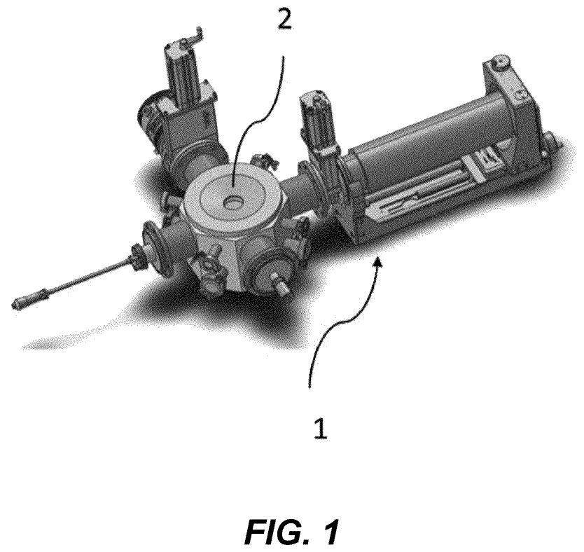

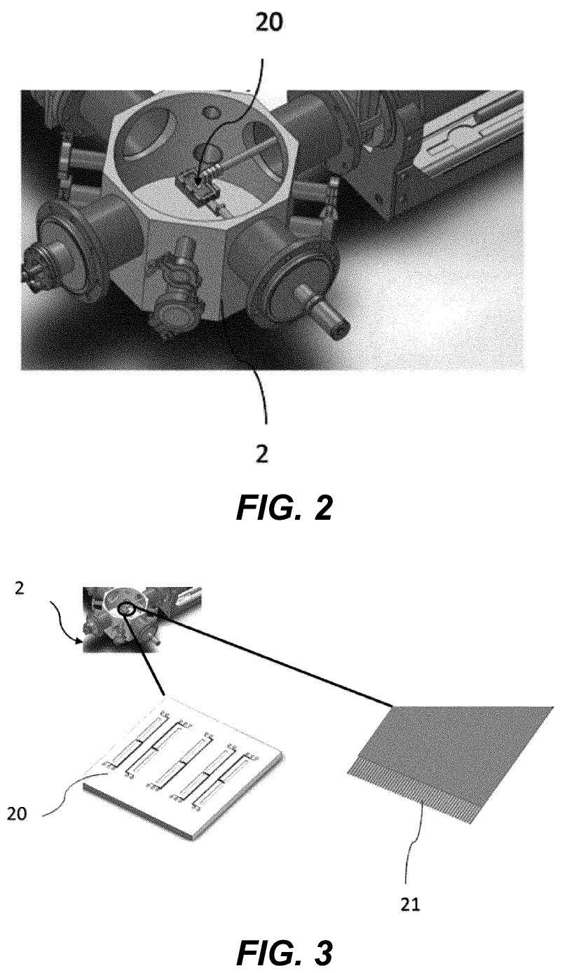

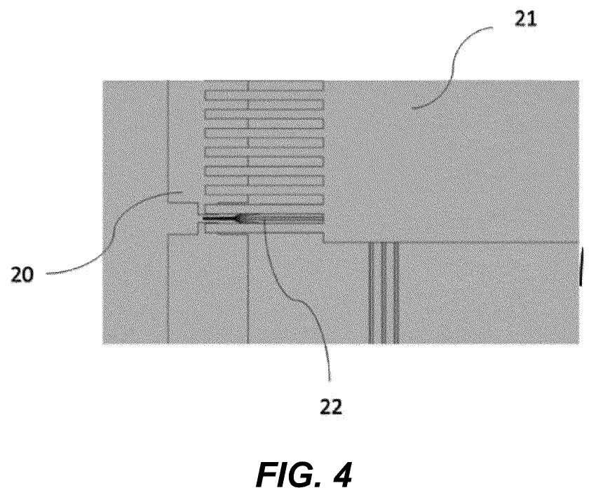

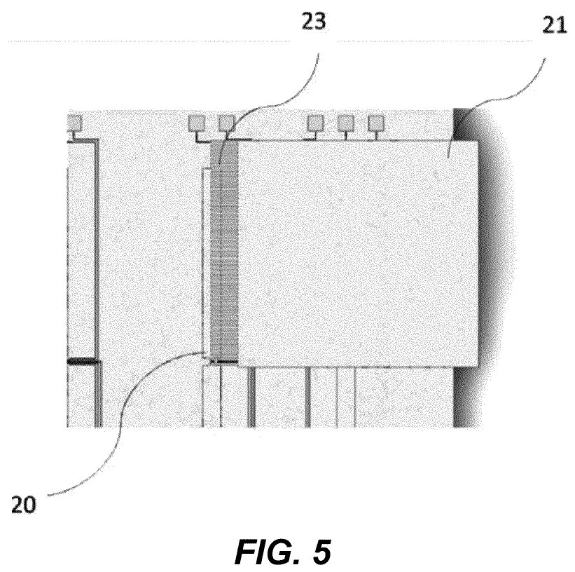

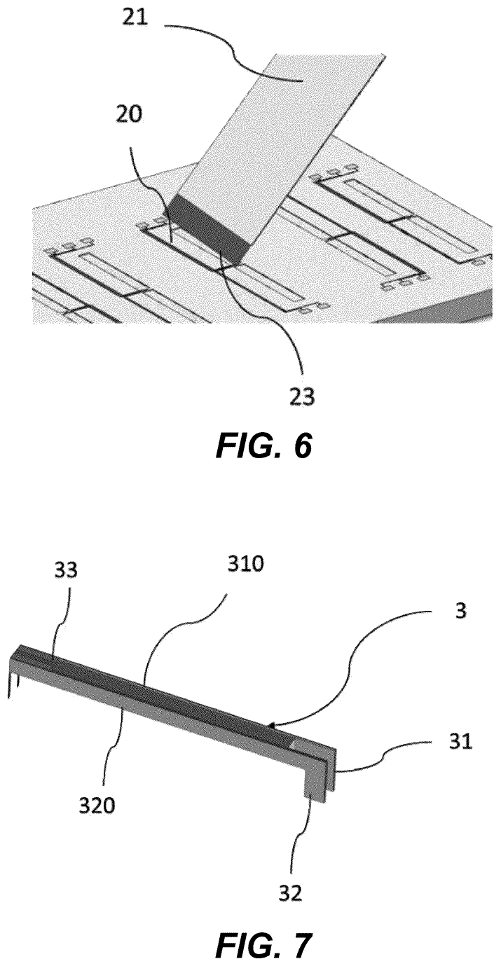

### DETAILED DESCRIPTION

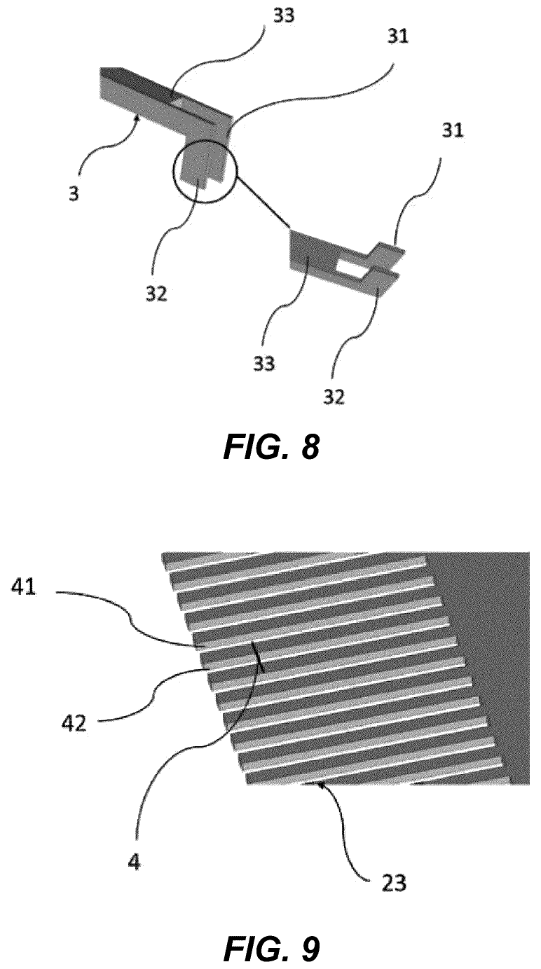

With reference to FIGS. 7 and 8, an example of a cantilever transfer device 3 will first be described. This cantilever transfer device 3 comprises two elongated blades 310, 320 separated by a piece of insulating material. These two blades 310, 320 have a bent arm 31, 32 at one end and a part at the other end for attachment to a mechanical fastening device (not shown) located in a fastening chamber.

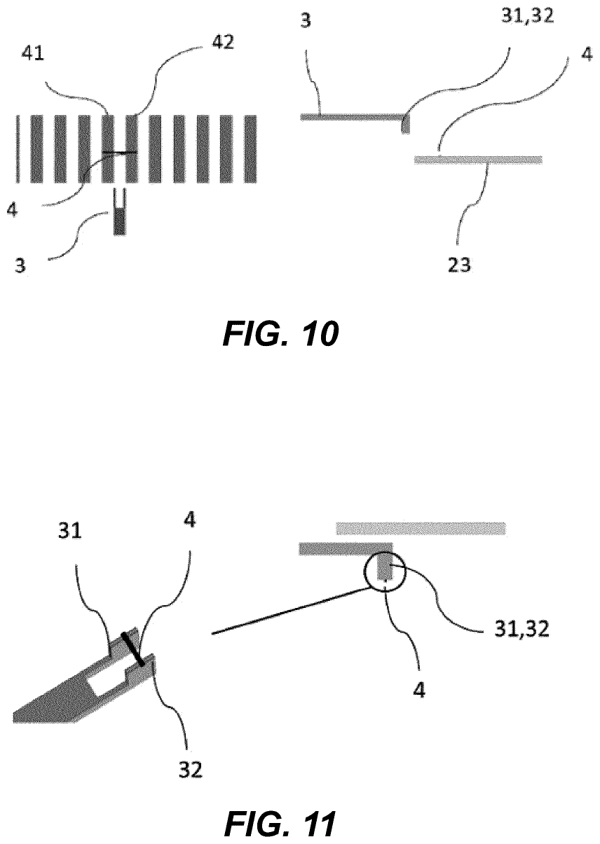

The cantilever transfer device 3 is designed to pick up a carbon nanotube 4 arranged on cantilevers 41; 42 of a support structure 23, as shown in FIGS. 9 and 10.

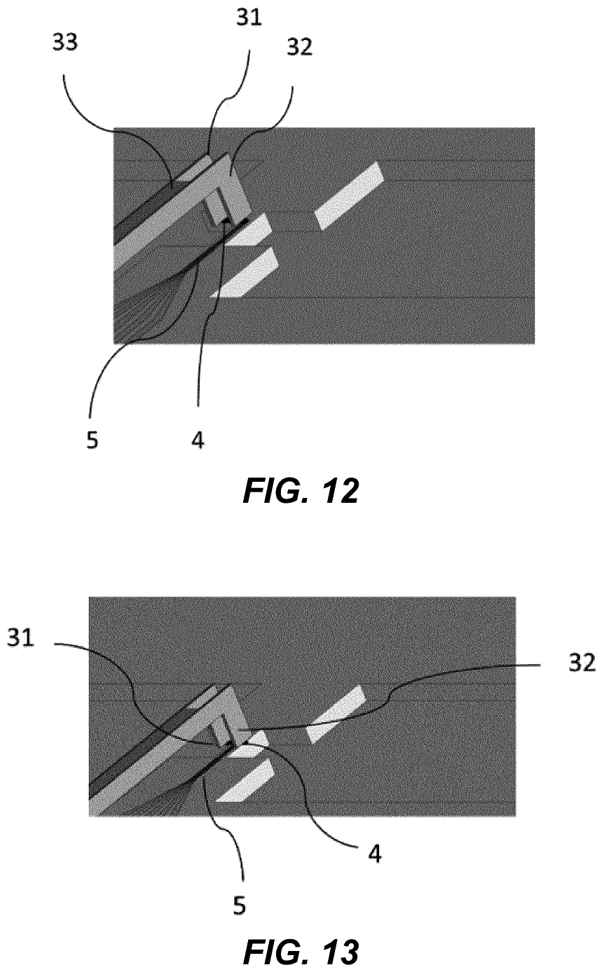

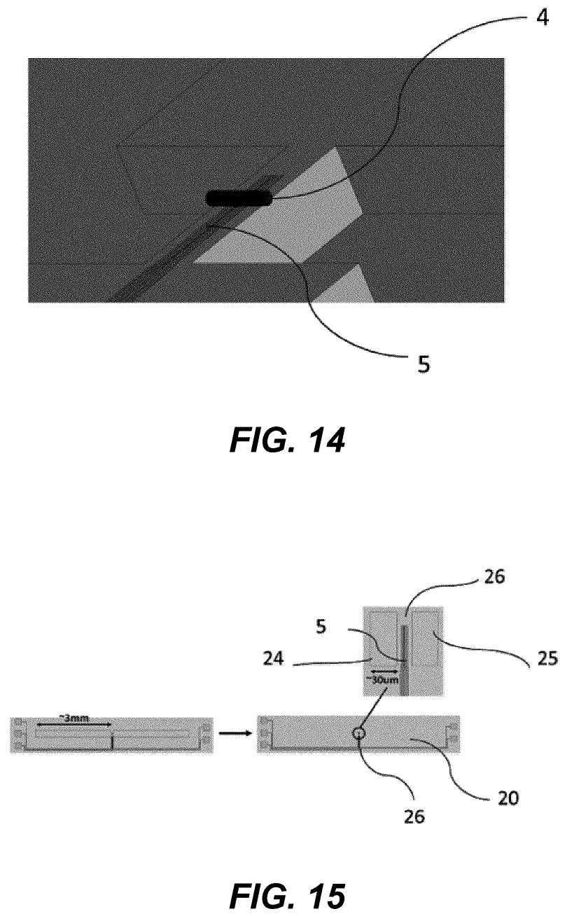

When the arms 31; 32 of the cantilever transfer device 3 come into contact with the nanotube 4, the latter is held in place by Van Der Waals forces. The transfer device 3 can then take the nanotube to a receiving structure, as shown in FIGS. 11 and 12. The cantilever transfer device 3 carrying the nanotube 4 approaches a receiving structure housing an electronic chip 5 arranged between two trenches, then deposits the nanotube 4 on the chip 5, as shown in FIGS. 13, 14 and 17.

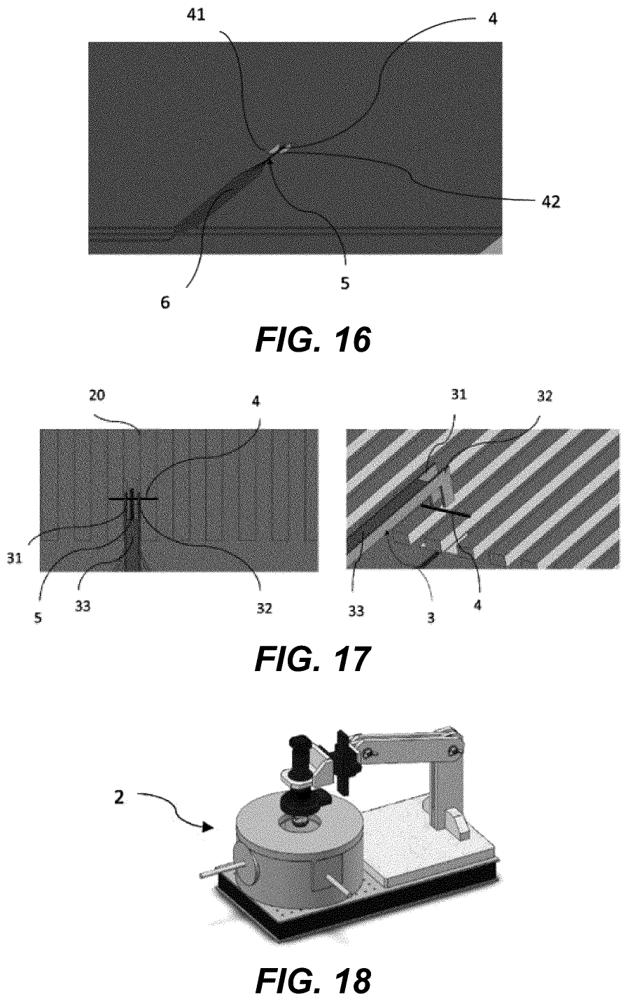

It should be noted that the transfer and deposition technique provided by embodiments of the present disclosure makes it possible to significantly reduce the width of the trenches of the receiving structures, as shown in FIGS. 15 and 16. This enables a switch from a trench width of around 3 mm to a trench width of around 30 μm. In this way, the receiving chip 5 is positioned on a protruding part 26 between two very thin trenches. The nanotube 4 can then be deposited on the receiving chip 5 arranged between two trenches 41, 42 and connected to a circuit 6 arranged on the receiving surface 20, as shown in FIG. 16.

In the nanotube deposition method according to the present disclosure, an intermediate fork, in the form of the cantilever transfer device, is used to perform two transfers of a target carbon nanotube. Firstly, the fork is essentially used to “pull out” a nanotube suspended between two cantilevers on a cantilever growth chip with a comb structure. After this transfer, the nanotube is attached to the end of the fork, suspended between its two tines. The fork with the attached nanotube is then brought into contact with the chip of a qubit device to precisely transfer this nanotube onto source and drain electrodes, suspended above an array of gate electrodes. A more detailed overview of the intermediate fork design and transfer processes is given below.

The intermediate fork—or cantilever transfer device-consists of two microfabricated tines attached to a rectangular support base. The fork and its base can be fabricated from an insulating material such as silicon or silicon nitride (the specific material is irrelevant) using conventional lithography and etching techniques. The tips of the tines must be metallized and electrically connected to the flares of the support base, either by evaporation coating or lithography. This connectivity is essential for the second transfer process to the qubit chip and can also facilitate the first transfer from the growth chip.

The width of the fork is limited by the requirement to fit between cantilevered pairs on the growth chip for the first transfer (around 30 μm). The gap between the fork tines must be large enough for the outermost qubit device electrodes to fit between the tines for the second transfer (around 10 μm). The tines must also be long enough for the tip of the fork to be easily resolved with an optical microscope when oriented at a small angle (around 2 degrees) to the normal, as shown in FIG. 13. It is also necessary for the tines to be significantly longer than the thickness of the growth cantilevers and the depth of the trenches/pits on the qubit chip, to facilitate easy transfer of the nanotube. Consequently, tines of the order of 100 to 500 μm in length are required. Finally, the tines must be thick enough to provide a large enough surface area for the nanotube to attach to their tip during the first transfer, and should therefore be around 10 μm thick. This thickness also impacts the mechanical strength of the tines, which are designed to survive numerous nanoassembly cycles.

The first transfer begins by optically aligning the tip of the fork above the location of the target nanotube suspended between two cantilevers on the growth chip. Once aligned, the fork is then lowered to bring the metallized fork tips into contact with the suspended nanotube.

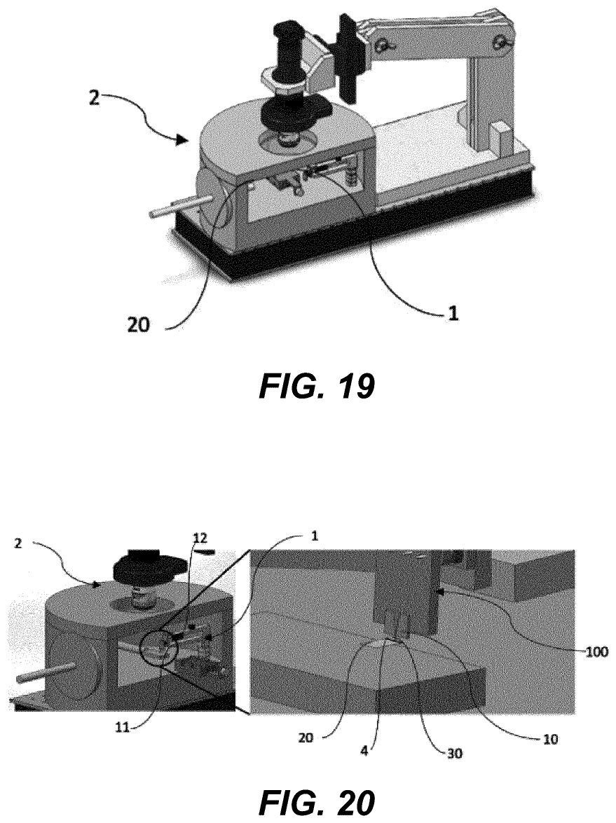

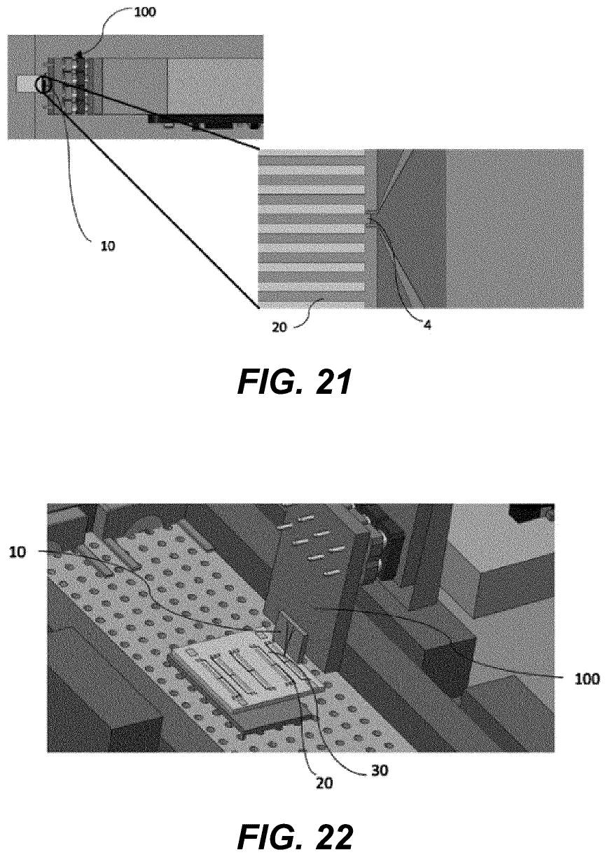

With reference to FIGS. 18 to 24, a particular embodiment of a fastening system according to the present disclosure will now be described, providing detection of the contact of the cantilever transfer device with the receiving surface and implementing an atomic force microscope architecture.

Document WO2021/009290A1 (Niguès et al.) discloses an atomic force microscope for evaluating a sample surface, comprising a sample holder, having a first zone adapted to receive the sample fixedly mounted, a probe having a tip adapted to be positioned facing the sample surface, the microscope being configured to allow adjustment of a position of the tip relative to the surface and a support, the sample holder having at least one second zone, distinct from the first zone and fixed relative to the support, the sample holder being deformable so as to allow relative displacement of the first zone relative to the second zone, and the microscope comprising a detector suitable for detecting displacement of the first zone relative to the second zone.

The MicroMegascope document (Canale et al.), 2018 [4], discloses an atomic force imaging device with a centimeter-sized oscillator. This device makes it possible to produce topographic images with nanometer resolution, using a centimeter-sized tuning fork or mechanical resonator equipped with an accelerometer to measure resonator oscillation.

An AFM (Atomic Force Microscope) technique can be used to detect when the tip of the cantilever is close to the trench. The problem was that this required a substantial change to the cantilever design. In AFM technology, the oscillator is very small and difficult to integrate into any design.

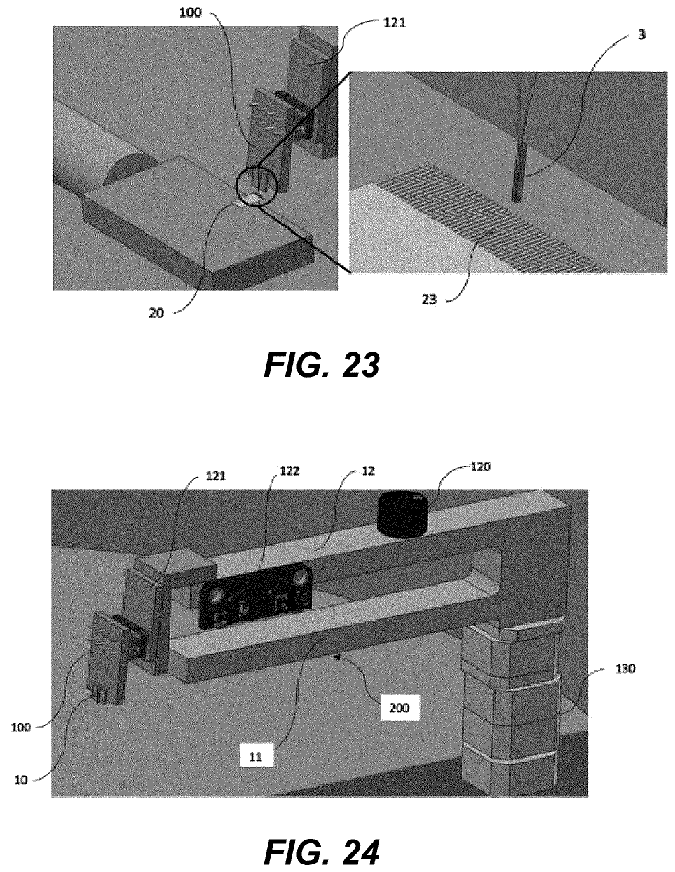

The fastening system includes, with reference to FIGS. 23 and 24, a forked transfer probe 10 coupled to a tuning fork 200 (or mechanical resonator) and nanopositioner assembly. To take advantage of AFM detection during the transfer process, fork probe 10, in the form of a microchip attached to printed circuit board 100, is attached to the end 121 of a tuning fork or mechanical resonator-inspired by the micromegascope described in the aforementioned document [4]-which is mounted on a stack 130 of x/y/z nanopositioning motors.

The vibration of the tuning fork 200 is driven by a piezoelectric actuator 120 mounted on top of the tuning fork 200. A MEMS (Micro Electro Mechanical Systems) accelerometer chip 122, attached to the side of the tuning fork 200 near the tip, is used to detect the movement of the tuning fork 200. The forked probe 10, as attached to the end of the tuning fork 200, will transduce the interactions between its tip and the surfaces/nanotubes during the transfer process, disturbing the vibration of the tuning fork 200.

These changes in vibration of the tuning fork 200 are then measured by the accelerometer and electrically coded. A phase-locked loop (PLL) controller (external electronics, not shown) is used to retract and extend the nanopositioning motor along the z-axis according to the signal from accelerometer chip 122. The phase-locked loop PLL can then be configured to trigger an alarm when the tip of the fork probe 10 comes into contact with a nanotube or surface 20, and to avoid collisions by maintaining a safe separation between the tip of the forked probe 10 and the surface of the quantum circuit chip.

Of course, the present disclosure is not limited to the examples that have just been described, and many other configurations may be envisaged without departing from the scope of the invention as defined by the claims.

1. A method for depositing at least one nano-object on a receiving surface, this nano-object being initially located on a cantilever chip having a comb structure, the method comprising:
picking up the nano-object using a cantilever device or transfer fork comprising two spaced-apart arms each including a tine, the two tines facing each other and arranged to pick up, hold and release the nano-object;
transferring the picked-up nano-object to the receiving surface; and
depositing the nano-object on the receiving surface.

2. The deposition method of claim 1, wherein the depositing of the nano-object on the receiving surface comprises depositing the at least one nano-object on electrodes separating trenches.

3. The deposition method of claim 2, wherein during the depositing the at least one nano-object, the arms of the cantilever transfer device penetrate into two trenches surrounding an electrode.

4. The deposition method of claim 3, wherein the trenches between electrodes are less than 100 μm wide.

5. The deposition method of claim 1, further comprising detecting when the cantilever transfer device has come into contact with the receiving surface using an atomic force probe, the atomic force probe comprising a tip carrying the cantilever transfer device and being attached to a tuning fork or mechanical resonator, the tuning fork or mechanical resonator being frequency-controlled around a predetermined resonant frequency.

6. The deposition method of claim 5, wherein the detecting comprises providing distance information relating to a distance between the tip carrying the cantilever transfer device and the receiving surface, the transferring being controlled using the distance information.

7. The deposition method of claim 6, wherein the nano-object comprises at least one carbon nanotube and the receiving surface is a receiving surface of a microelectronic circuit.

8. The deposition method of claim 7, wherein the receiving surface include electrodes.

9. The deposition method of claim 1, wherein the method is used to form at least a portion of a Qubit component.

10. A system for depositing at least one nano-object on a receiving surface comprising: at least one cantilever transfer device configured for picking up a nan-object located on a carrying surface, transferring the nano-object to a receiving surface, and depositing the nano-object on the receiving surface, the at least one cantilever transfer device comprising two spaced-apart arms each including a tine, the tines facing each other and arranged to pick up, hold and release the nano-object, the at least one cantilever transfer device being in the form of two substantially parallel blades separated by an insulating piece.

11. The deposition system of claim 10, wherein each blade comprises an elongate portion, one cantilevered end of the elongate portion having an arm substantially perpendicular to the elongate portion.

12. The deposition system of claim 11, wherein the arms have an electrically conductive coating.

13. The deposition system of claim 10, wherein the system is configured for deposition of at least one carbon nanotube on electrodes separated by trenches.

14. The deposition system of claim 13, wherein the trenches between electrodes are less than 100 μm wide.

15. The deposition system of claim 10, wherein the system is configured for fastening nanotubes onto a plurality of electrodes of an electronic circuit of a quantum dot.

16. The deposition system of claim 10, further comprises means for detecting when the at least one cantilever transfer device has come into contact or is at risk of contact with the receiving surface, the detection means comprising an atomic force probe having a tip carrying the at least one cantilever transfer device and attached to a tuning fork, the tuning fork being frequency-controlled around a predetermined resonant frequency.

17. The deposition system of claim 16, wherein the detection means further comprises means for outputting deviation information regarding a distance between the tip carrying the at least one cantilever transfer device and the receiving surface, and means for controlling the transfer means on a basis of the deviation information.

18. The deposition system of claim 17, wherein the system is arranged in a fastening chamber within a system for producing Qubit components.

19. A system for fastening carbon nanotubes to produce Qubit components, comprising a fastening chamber incorporating a deposition system according to claim 16.
